(19) United States
(12) Patent Application Publication
(10) Pub. No.: US 2015/0173227 A1
(43) Pub. Date: Jun. 18, 2015

(54) Component Casing for an Electronic Module

(71) Applicant: Robert Bosch GmbH, Stuttgart (DE)

(72) Inventors: Harald Ott, Freiberg Am Neckar (DE); Torsten Berger, Remseck Am Neckar (DE); Gerald Kammer, Ludwigsburg (DE)

(21) Appl. No.: 14/419,931

(22) PCT Filed: Jun. 6, 2013
(86) PCT No.: PCT/EP2013/061899

§ 371 Date: Feb. 5, 2015

(30) Foreign Application Priority Data
Aug. 6, 2012 (DE) 10 2012 213 917.6

(51) Int. Cl. H05K 5/06; H05K 3/00; H05K 7/02

(52) U.S. Cl. CPC H05K 5/065; H05K 7/02; H05K 3/0011

(57) ABSTRACT

An electronic module includes a printed circuit board element with at least one electronic component and a case element. The case element is at least partially connected to the printed circuit board element with a form fit. The at least one electronic component is arranged between the case element and the printed circuit board element. The form-fit connection of the printed circuit board element and the case element includes micro structuring of the printed circuit board element.

The present invention relates to electronic modules for vehicle control units. In particular, the present invention relates to a component casing for electronic modules for a control unit of a vehicle. More particularly, the present invention relates to an electronic module, to a control unit, to a vehicle, in particular an automobile, and also to a method for producing an electronic module comprising a component casing.

### PRIOR ART

Electronic modules for control units, for example for transmission control units, usually require a hermetically tight housing on account of their location, for example in an aggressive liquid. This is realized in conventional electronic modules by a cover element being applied, for example adhesively bonded, to a printed circuit board. The cover element can have a metallic configuration, for example, while the printed circuit board has a conventional form.

A suitable adhesive bond between the cover element and the printed circuit board is important for good sealing of the inner space formed by the printed circuit board and the cover element. Particular demands can be made of such an adhesive bond. If, by way of example, an electronic module is used as a component part of a transmission control unit in the transmission, it regularly comes into contact with aggressive transmission fluid. In addition, an electronic module of this type regularly experiences severe heating during operation. An adhesive bond therefore also has to afford a reliable seal in the case of heated operation. In particular, different coefficients of thermal expansion of the materials of the printed circuit board and of the cover element can bring about shearing forces in the adhesive bond.

### DISCLOSURE OF THE INVENTION

One aspect of the present invention can therefore be considered that of providing an improved component casing for components of an electronic module.

Provision is accordingly made of an electronic module for a vehicle, of a control unit for a vehicle, of a vehicle, in particular an automobile, and also of a method for producing an electronic module as per the independent claims. Preferred embodiments become apparent from the dependent claims.

The invention provides an electronic module, which firstly comprises a printed circuit board element. At least a partial region of this printed circuit board element is provided with at least one electronic component, which is connected to the printed circuit board element, in particular the conductor tracks thereof. These conductor tracks can be routed in the interior of the printed circuit board element proceeding from the electronic component, for example, and leave it in turn at a remote location, in order for example to connect electrical connection technology such as sensors or actuators.

According to the invention, the at least one electronic component is now enclosed by a casing element. In this respect, the casing element has an inner space, in which inner space the at least one electronic component is arranged. The inner space between the casing element and the printed circuit board element can correspond substantially to the electronic component, in which case the casing element may have been cast around the latter, for example, or else the casing element itself can have a relatively large inner space, and therefore, for example, form a hollow space in which the at least one electronic component or else a multiplicity of electronic components are arranged.

According to the invention, the casing element is now connected to the printed circuit board element not (exclusively) with a force fit, but rather (at least partially) with a form fit.

An appropriate form fit is provided according to the invention by virtue of the fact that, before the application of the casing element, the printed circuit board element has a three-dimensional microstructure at least in a partial region in which the casing element is also arranged. Such a microstructure of the printed circuit board element can be generated, for example, by treatment of the printed circuit board element. In other words, a minor, desired irreversible change to the surface of the printed circuit board element is generated, for example, by a laser beam, as a result of which the surface in the region of the microstructuring can have such a surface which is suitable for providing a casing element, which is molded on for example after the microstructure has been generated, with a sufficient base for form-fitting anchoring on the surface. Expressed differently, the surface can be partially and minimally destroyed or roughened by way of the laser treatment, such that a plastics part molded on subsequently can form a form fit with said surface.

A printed circuit board element is therefore provided at least partially with a microstructure on its surface by a laser treatment or another suitable forming process. A plastics compound is subsequently connected at least partially to the printed circuit board element in a firmly adhering and tight manner in an injection molding process. On account of the microstructuring, the surface of the printed circuit board element therefore provides a suitable surface in this region for forming a form-fitting connection with a subsequently molded on plastics material.

Such microstructuring according to the invention therefore represents a cost-effective and simple way of implementing a connection between a printed circuit board element and a plastic. This makes it possible to achieve new sealing concepts between the printed circuit board element and plastic. Known printed circuit board elements in this respect have a high temperature resistance and are therefore suitable for a plastic encapsulation process. A separate surface cleaning process, for example before the adhesive bonding of elements, can be dispensed with, particularly when the casing element is molded on directly after the surface structuring operation.

According to the invention, the printed circuit board element used can be a conventional printed circuit board or else also a flexible printed circuit board (Flexible Printed Circuit FPC). It is also conceivable, for example, to microstructure a conductor track running on the surface of the printed circuit board element. In this respect, adaptation of the microstructuring process may be required, for example adaptation of the power of a laser beam.

Within the context of the present invention, a printed circuit board can similarly be understood to mean in general terms a circuit carrier which has a partial microstructure on the surface and, for example, has integrated metallic conductors or metallic conductors which run at least partially on the surface. By way of example, this may be a thermoplastic or thermosetting plastic (reinforced or non-reinforced) with embedded or injected metallic conductors, e.g. a PCB or FPC with integrated conductors, a plastics part with integrated lead frames or wires as conductors or else a ceramic circuit carrier. Within the context of the present invention, the expression printed circuit board should therefore not be construed in a limiting manner as an element of cured epoxy resin with integrated glass fiber mats. This therefore represents merely an exemplary example to which the description of the figures hereinbelow refers.

Embodiments of the invention are shown in the drawings and will be explained in more detail in the description hereinbelow.

In the drawings:

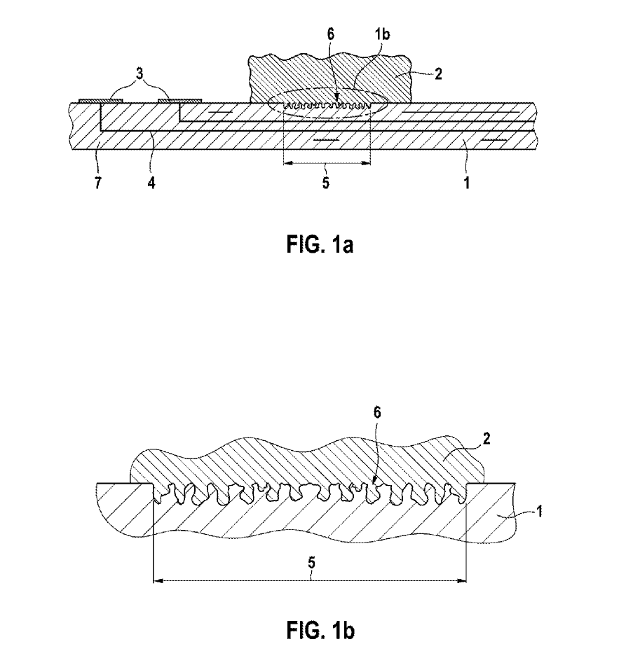

FIGS. 1a, b show the microstructuring principle according to the invention;

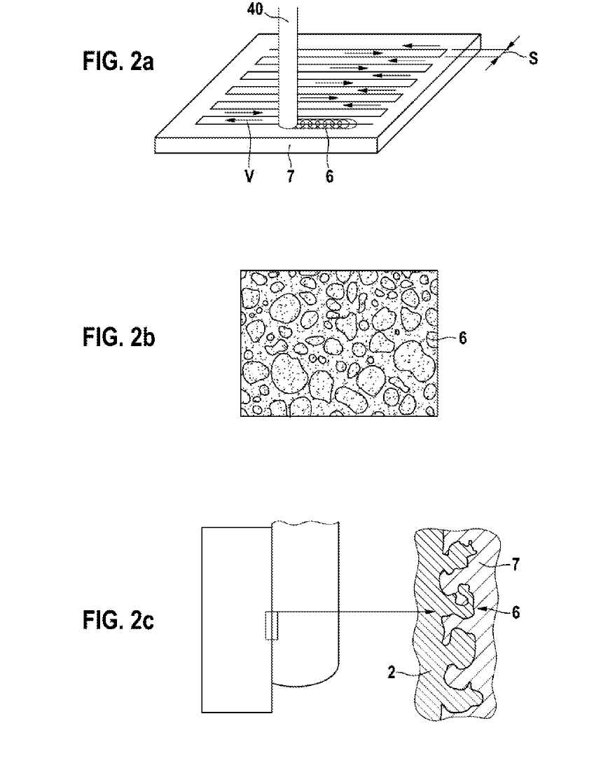

FIGS. 2a-c show an exemplary method for microstructuring;

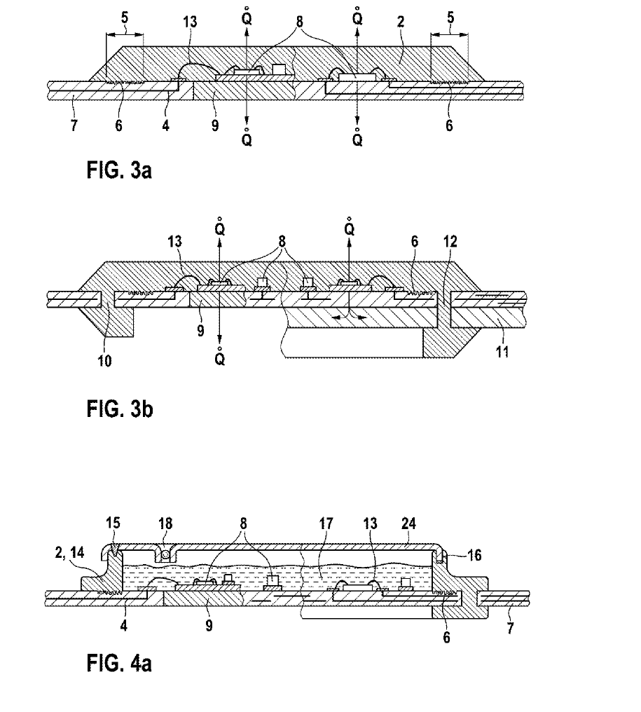

FIGS. 3a-8c show exemplary embodiments of an electronic module according to the present invention.

### EMBODIMENTS OF THE INVENTION

The microstructuring principle according to the invention is shown with further reference to FIGS. 1a, b.

FIG. 1a firstly shows a printed circuit board element 7, formed in an exemplary manner from cured epoxy resin with integrated glass fiber mats.

Conductor elements 4, formed for example as copper conductors, are arranged at least partially in the interior of the printed circuit board element 7 and, at a defined location, protrude through the surface of the printed circuit board element 4, where they are terminated, for example, using contact elements 3 or contact pads. The contact elements 3 can have different surface coatings, for example gold or tin.

The surface of the printed circuit board element 7 is subjected to a surface treatment in a defined region 5 and microstructured 6 in the process. The microstructure 6 can be generated, for example, by a laser process, in which a laser beam is applied to the surface. The microstructuring 6 can in this case be effected partially, and therefore affect only part of the surface of a printed circuit board element 7, and can in particular be circumferential, and therefore for example circumferentially surround an electronic component arranged on the surface. It may thereby be ensured that the component can be surrounded by a casing element which is applied to the microstructuring 6 and bonds securely to the surface of the printed circuit board element.

In an encapsulation process step which follows the microstructuring step, a casing element 2, formed for example as a plastics compound 2, can be arranged or molded on in the region 5. This plastics compound can be a thermoplastic or thermosetting plastic, for example, the coefficient of thermal expansion of which is matched to the coefficient of thermal expansion of the printed circuit board element 7, if appropriate by using suitable fillers and reinforcing materials.

In this case, the casing element 2 can encapsulate the region 5 or may only be overmolded in the region of the microstructuring 6. Thus, for example, a suitable receiving means can be connected fixedly to the printed circuit board element surface and is then suitable or set up for providing further elements, for example for covering or hermetically sealing components on the printed circuit board element 7.

During the injection molding process, the at least partially liquid compound of the casing element, for example a liquid plastics compound, penetrates into the microstructures 6 of the printed circuit board element 7 and fills the latter. The subsequent cooling gives rise to a fixed and tight connection between the casing element 2 and the microstructuring 6. On account of the configuration of the microstructuring 6, as can be gathered for example from FIG. 1b, the casing element 2 and the microstructuring 6 enter into a form-fitting connection.

An exemplary method for microstructuring is shown with further reference to FIGS. 2a-c.

FIG. 2a shows by way of example a printed circuit board element 7. FIG. 2a can in this respect symbolize a section of a larger printed circuit board. What is shown by way of example is a microstructuring method in which a laser beam 40 passes over the surface of the printed circuit board element 7 and in the process produces the microstructuring 6. By way of example, the laser beam 40 moves linearly in the direction V and in the process produces a microstructured track of width S.

After a track has been completed, it is possible, for example, for the direction of movement of the laser beam to be inverted and for a further track to be microstructured directly alongside said track which has just been produced. By virtue of the laser beam passing repeatedly over the surface of the printed circuit board element 7, it is therefore possible for a surface as shown in FIG. 2b to be produced. This surface has microstructuring 6, to which a suitable plastics compound or the like, generally a casing element 2, is then applied in a subsequent injection molding process, with the latter being connected to the microstructured surface. FIG. 2c shows in this respect, again in detail, the flowing of the material of the casing element 2 into the microstructured 6 surface of the printed circuit board element 7 and the resulting form-fitting connection.

The laser beam therefore structures the surface by a defined deflection of the laser beam, e.g. using a galvo scanner. The surface of the printed circuit board element can in this respect be scanned with ultra-short laser pulses, as a result of which a micro/nanostructure is produced. Then, the components are encapsulated with a thermoplastic or adhesive. Here, the polymer or the adhesive penetrates or flows into the multi-scale structure and in the process produces a fixed and tight connection.

Instead of a (rigid) printed circuit board, the printed circuit board element 7 can also be realized as a flexible printed circuit board (FPCB). The power of a laser used for the microstructuring 6 may have to be adapted to the film structure of the flexible printed circuit board.

The text hereinbelow describes a number of technical embodiments which can be used, for example, in transmission control modules, the control unit thereof and the functional elements thereof.

FIG. 3a shows an exemplary embodiment of an electronic module according to the invention with a tight molding package, which has been molded directly onto the printed circuit board element 7.

A surface of the printed circuit board element 7 has in turn been partially and circumferentially microstructured 6 by a laser. Electronic components 8 are arranged on the surface and are connected, for example, to contact surfaces 3 and furthermore the conductor elements 4 using connecting elements or bonds 13. These components 8 arranged on the surface of the printed circuit board element 7 are then furthermore intended to be protected by the casing process according to the invention. Using a suitable encapsulation mold, the casing element 2, initially in the form of a liquid plastics compound for example, is therefore applied to the printed circuit board element 7 and in the process in particular to the region 5 of the microstructuring 6. These microstructures 6 are therefore filled with the plastics compound 2, and the components 8 are covered in the process. This gives rise to a tight protection of the electronic components from transmission oil, for example, after the plastics compound 2 has been cooled.

As shown in FIG. 3a, the printed circuit board element 7 can in this case have a heat-conducting element 9, for example a metal inlay made of copper, at a suitable location, in order to thereby provide improved heat dissipation Q from the electronic components 8.

FIG. 3b now shows a molding package which has been injected partially through the printed circuit board element 7.

FIG. 3b is in this respect substantially comparable to FIG. 3a, the printed circuit board element 7 having cutouts 10, 12 at a suitable location. Using suitably designed molds, the molding compound 2 can penetrate through the cutouts 10, 12 during molding and pass to the second side, the side on the bottom in FIG. 3b, of the printed circuit board element 7. A shape can be introduced into the plastics compound 2 on this opposing side using suitable molding tools, and therefore a form fit also arises on the opposing side. It is thereby possible to provide better mechanical contact or improved fastening of a cooled molding compound 2. An embodiment as per FIG. 3b may also reduce sagging of the electronic module, since the plastics compound 2 arises on both sides of the printed circuit board element and thereby ensures that there is a stress equilibrium.

FIG. 3b similarly shows the realization of an integrated metal inlay 9 in the printed circuit board element 7. On the right-hand side of FIG. 3b, provision is made, in addition to the printed circuit board element 7, of a carrier element 11, for example a metal plate, which likewise has a cutout 12, such that the molding compound 2 can flow through both the printed circuit board element and the carrier element 11 and encompass the latter with a form fit from the side on the bottom in FIG. 3b.

One aspect of FIGS. 3a, b is the molded encapsulation of the electronic components 8 after they have been assembled and contact-connected. If this is not desirable, the exemplary embodiments hereinbelow can realize advantages of a simple control unit housing concept which can be constructed step by step and, for example, disassembled simply for analysis, without the molding compound 2 or the casing element 2 having to be removed by a complicated method.

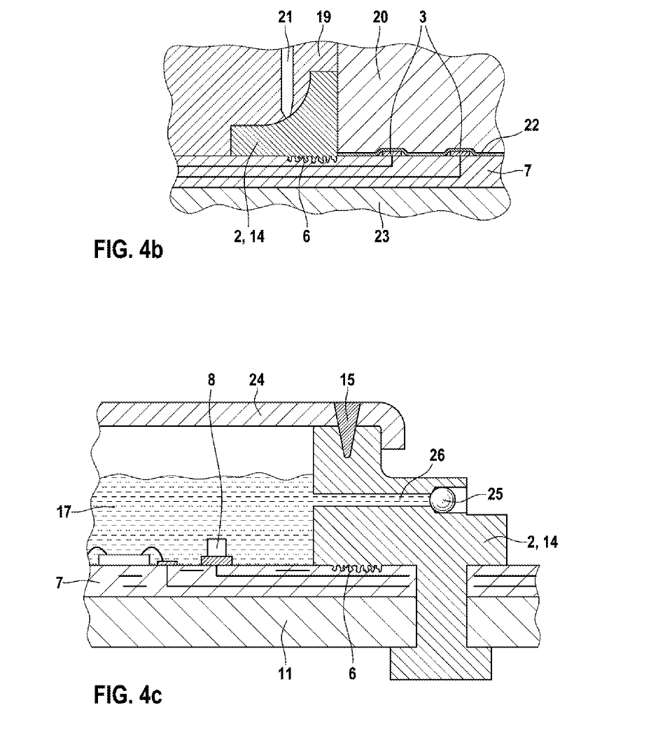

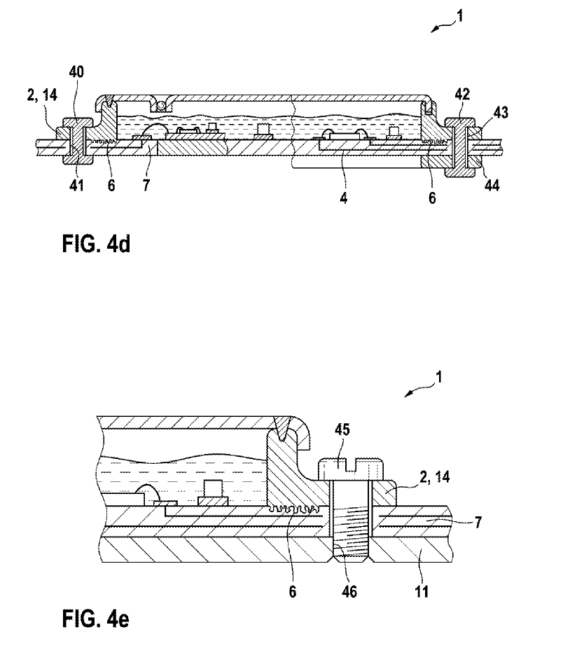

FIGS. 4a-e now show an electronic module according to the invention having a frame structure.

It can be seen in FIG. 4a that the surface of the printed circuit board element 7 is again formed with a microstructure 6. A frame-shaped structure 14 is then applied to, for example molded on, said microstructuring 6 and in the process is connected in a form-fitting manner to the microstructuring 6 in a known manner, as described above. A thermoplastic or thermosetting plastic penetrates into the microstructures 6 of the printed circuit board element 7 in the process and, after cooling, forms a frame 14, which has a sealing action in relation to the printed circuit board element 7 and is made up of the casing element 2 or the potting compound thereof. The partial penetration of the casing element 2 through a suitable opening in the printed circuit board element 7 is shown by way of example in turn.

After the frame structure 14 has been applied to or through the printed circuit board element 7 and the microstructure 6 thereof, the printed circuit board element 7 can be subjected to a pick-and-place operation, that is the printed circuit board element 7 can be equipped with electrical components or component carriers 8. The electrical connection to the conductor elements 4 arranged in the printed circuit board element 7 can again be made by connecting elements 13.

To seal off the electronic module, in particular the inner space of the casing element or the electronic components 8 arranged there, from the outer region, it is possible to place on a cover element 24, preferably made of a plastic or metal, in particular a plastic which is identical or similar to that of the frame structure 14, and to connect it tightly to the housing frame or the frame structure 14, as shown in the region 15 in FIG. 4a, by ultrasonic plastic welding or laser plastic welding, for example. In general terms, 15 can be configured as any desired, suitable welding operation or as a connecting process of a differing type.

An alternative possibility for forming a connection is shown in the region 16, this being in the form of a groove which runs in the frame structure 14 and into which the cover element 24 can be introduced in a suitable manner, for example it can be tightly adhesively bonded or molded there. The cover element 24 can furthermore also have an opening 18. Once the cover element 24 has been connected tightly to the frame element 14, this opening 18 can be used to carry out a leak test in such a manner as to test the extent to which the inner space of the electronic module is tight. Once the leak test has been performed, a potting compound 17, for example a gel, can be introduced if appropriate, depending on the application, and fills the inner space partially or completely. The opening 18 can be closed tight in a known manner using a suitable element, for example using a spherical element pressed into the opening 18.

So as not to damage or contaminate possibly sensitive contact-connecting surfaces 3 lying on the surface of the printed circuit board element during an injection molding operation of the frame structure 14, before the molding operation the surface of the printed circuit board element can be provided at least partially with a suitable cover, for example a self-adhesive and heat-resistant protective film 22. By way of example, this can be produced from polyimide and can be removed again after the molding operation and before population with electronic components 8. What are shown by way of example are mold constituent parts 19, 20 and 23, these forming a cavity which corresponds substantially to the shape of the frame structure 14. A suitable opening, for example an injection runner 21, can be provided in order to introduce the material of the frame structure into the formed cavity. This is shown by way of example in FIG. 4b.

As shown in FIG. 4c, it is possible in turn for a carrier element 11, for example a metallic carrier plate, to be integrated in the structure. The material of the casing element or of the frame structure 14 can then at least partially penetrate through the printed circuit board element 7 and also the carrier element 11 via suitable openings arranged in relation to one another therein and connect these two elements with a form fit on the side lying opposite the components 8. The metallic carrier element 11 also makes it possible to achieve an improved dissipation of heat, in particular in combination with the metal inlay 9. The carrier element 11 can therefore be regarded in general terms as a heat sink.

As shown in FIG. 4c, the casing element 2 or frame structure 14 can have an opening, for example a test bore 26 formed parallel to the printed circuit board element 7 in the housing frame 14. The function of this test bore 26 can be comparable with that of the opening 18. Here, too, a filler material 17, for example a gel, can be introduced into the interior of the electronic module after complete construction of the electronic module. The test bore 26 can in turn be closed tightly with a suitable closure element, for example a sphere pressed into the plastics material of the frame element 14.

A further exemplary embodiment of an electronic module according to the invention is shown with further reference to FIG. 4d.

FIG. 4d corresponds substantially to the structure of FIG. 4a here, with a different or additional possibility for fastening the casing element 2 or the frame structure 14 to the printed circuit board element and/or a carrier element 11 which is possibly provided. In FIG. 4d, the frame element 14 or the housing frame molded on is connected to the printed circuit board element 7 by mechanical fastening elements. Suitable for this purpose are, for example, riveting elements 40, 42, which are located in particular outside the microstructuring 6 and interact with bores 41, 43 or in general terms openings in the printed circuit board element 7.

These fastening elements can absorb forces which arise here, in particular a large part of a force which arises compared to the microstructuring 6, and as a result can relieve the latter of loading. Forces which arise through different coefficients of thermal expansion of the casing element 2 and of the printed circuit board element 7 could therefore be absorbed, for example, and therefore the microstructuring 6 may undertake substantially only a sealing function. Additional fastening elements can therefore realize a sealing function with a higher reliability.

As indicated above, a carrier element 11 is furthermore also provided in FIG. 4e. The fastening element in FIG. 4e is, by way of example, a screw element 45, which in turn engages through suitable openings in the casing element 2 or frame element 14 and also the carrier element 11. A metallic carrier element 11 can in this respect have a thread, with which the screw element 45 can be brought into engagement and thus fastened. Here, too, the microstructuring 6 may provide substantially a sealing function.

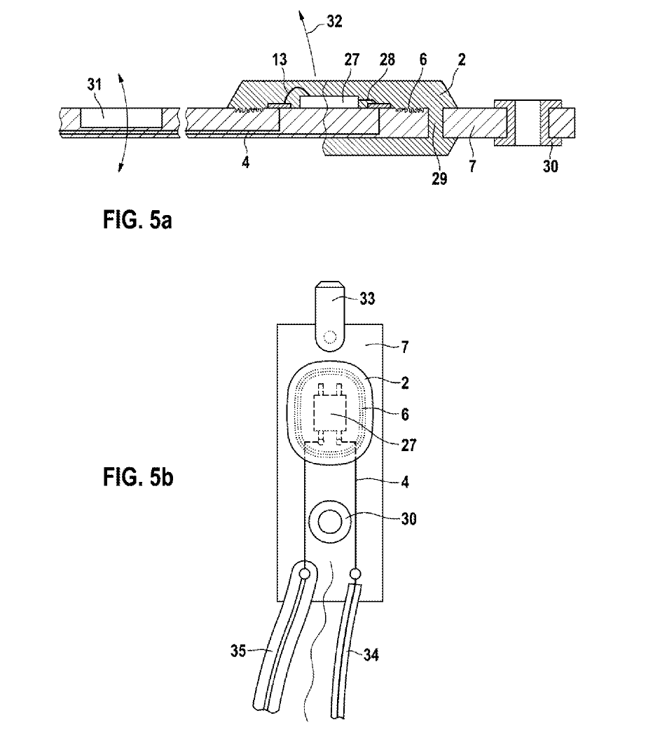

FIGS. 5a, b show an embodiment of the electronic module according to the invention in which a sensor element is encapsulated directly with the casing element 2. By way of example, this therefore represents a tight ASIC encapsulation of a sensor, for example of a speed sensor.

FIG. 5a in this respect shows a simplified sensor structure directly on the printed circuit board element of, for example, a control unit. The sensor 27, for example an ASIC (Application Specific Integrated Circuit), can be fastened suitably directly on the printed circuit board element 7 and can be connected to conductor elements 4 in the interior of the printed circuit board element 7 by contact elements 13, for example bonds, or else direct SMD solders 28.

The microstructuring 6 on the surface of the printed circuit board element 7 in this case at least partially surrounds the sensor element 27 and the contact connection thereof. Then, after the printed circuit board element 7 has been populated with the sensor element 27, a tight package of the sensor element 27 can in turn be realized by encapsulation with a casing element 2 made of a suitable plastic.

Depending on the design of the injection molds, further functional regions can be realized on or in the printed circuit board element 7 thereafter or during the same injection molding operation. By way of example, a plastics fastening bushing 30 can be attached.

In order to bring the sensor region of the electronic module as shown in FIG. 5a into its preferred sensor position, a region 31 of the printed circuit board element 7 can be provided with a partially flexible form. As a result, the printed circuit board element 7 can be bent and, for example, pivoted in the direction 32 and fastened. Depending on the desired embodiment, the material of the casing element 2 can partially penetrate through the printed circuit board element in the region 29, for example, and encompass it in a form-fitting manner on the rear side.

FIG. 5b also shows a sensor element 27 according to the invention built up on a printed circuit board element 7. Comparably to FIG. 5a, the sensor element 27 is connected to conductor elements 4 of the printed circuit board element 7 and is surrounded by a casing element 2 in the region of the microstructuring 6.

At the same time as the molding operation of the casing element 2, it is possible in turn for a fastening bushing 30 and also a centering pin 33 to be applied by injection molding. At a suitable point outside the casing element 2, the external connection to the sensor element 27 can be made, for example, via a flexible printed circuit board 35 or else via a cable conductor 34, which can be soldered onto the printed circuit board element, for example.

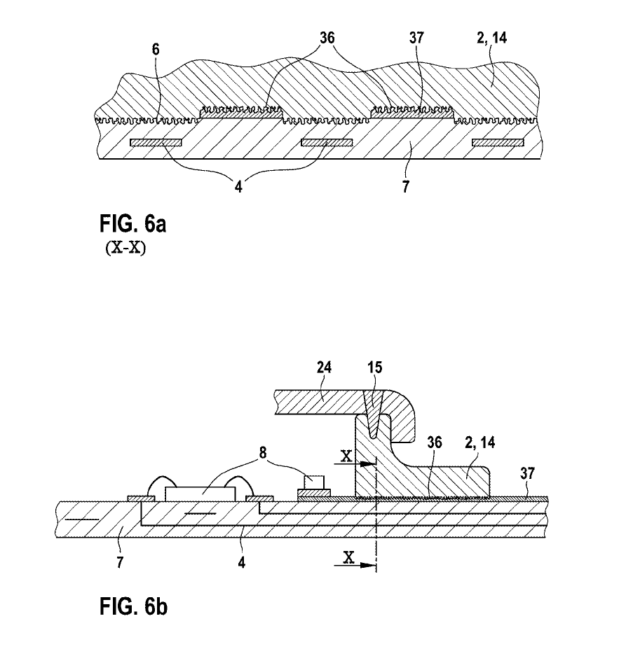

FIGS. 6a, b show an electronic module having a tight molding package injection molded directly on the printed circuit board element and also conductor elements located on the surface.

FIG. 6a shows a printed circuit board element in which both the surface of the printed circuit board element 7 and also conductor elements 37 located on the surface are microstructured 6, 36. The structuring process of the circumferential surface can be effected in turn by laser structuring, for example. During this structuring process, the laser power can be set for the respective material, for example the printed circuit board element 7 or the conductor element 37, and therefore for example plastic or metal, so that both materials obtain suitable microstructuring 6, 36. A subsequently applied casing element 2 can therefore be connected with a form fit not only to the surface of the printed circuit board element 7 but also equally to the microstructured 36 surface of the conductor element 37.

Here, FIG. 6a represents a section X-X from FIG. 6b. In an encapsulation process which was effected after the microstructuring 6, 36 and in which, by way of example, a frame structure 14 was built up as shown in FIG. 6b, the tightness in relation to the frame element 14 is produced both over the surface of the printed circuit board element 6 and the surface of the conductor element 37, which in FIG. 6b runs, by way of example, on the surface of the printed circuit board element 7.

As described above, a subsequently mounted and sealed cover element 24 in turn completely tightly closes the inner space of the electronic module with respect to the outer region, although a conductor element 37 arranged on the surface is able to electronically connect components 8 from the inner space of the electronic module to the outer region.

It goes without saying that the individual aspects shown in the individual figures can be freely combined with all exemplary embodiments within the context of the inventive concept.

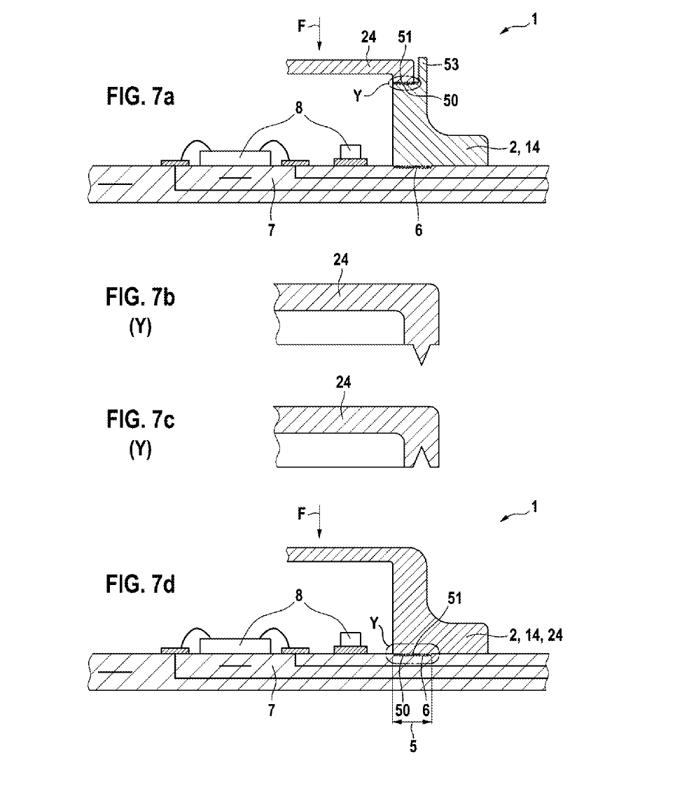

FIGS. 7a-c show a further embodiment of an electronic module according to the invention with a special structure of the frame element 14 and the cover element 24.

In this exemplary embodiment, a cover element 24 made, for example, of thermoplastic, partially crystalline plastic is provided. The marginal region of the cover element 24 and/or of the frame structure 14 can be melted by a suitable heating element and the elements can then be placed one into another.

It is similarly conceivable that the frame element 14 for its part is microstructured 50, such that a heated plastic from the cover element 24 forms a form fit 51 with this microstructuring 50. The heated cover element 24 is pressed onto the frame element 14 or pushed into it under the action of force in the region of the microstructuring 50, as a result of which a form fit arises in turn between the cover element 24 and the frame structure 14 in the microstructuring 50.

For better positioning of the cover element 24 in the X, Y direction, webs 53 for an end stop can be provided, for example applied by injection molding, on the outside of and in particular circumferentially on the frame element 14.

FIGS. 7b, c show various embodiments of the marginal region of the cover element 24 in this respect.

FIG. 7d in turn shows a further exemplary embodiment of an electronic module according to the invention having a casing element, which has a hollow space and can be brought directly into engagement with microstructuring 6 present on a printed circuit board element. The casing element 2 is in this case configured as a single-piece combination of the frame element 14 together with a cover element 24.

Here, the casing element 2 has an inner space, in which electronic components 8 can again be arranged, and can be produced, for example, from a thermoplastic material. A suitable heating element can be used to melt the casing element 2 in the region 5 in order that the latter can then be pressed or pushed under the action of force F into a suitable microstructure 6. It is thereby possible in turn to form a form fit 51 between the casing element 2 and the printed circuit board element 7.

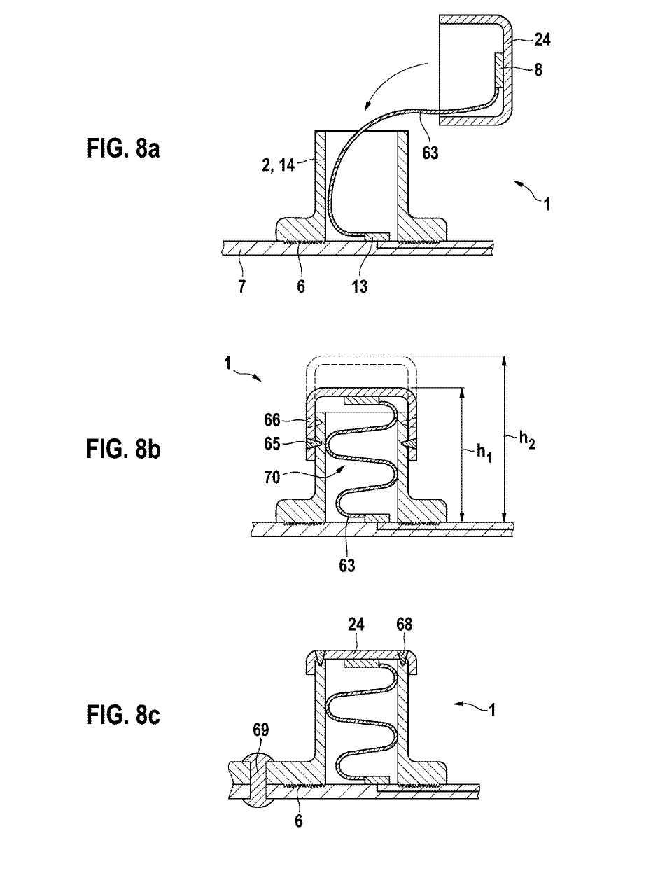

A further exemplary embodiment of an electronic module according to the invention as a sensor is shown with further reference to FIGS. 8a-c.

FIG. 8a shows, by way of example, a sensor housing, for example a speed sensor, preferably having a frame element 14 with a cylindrical design which is tightly connected in turn to a printed circuit board element 7 using a microstructure 6.

By way of example, an electronic component 8, for example a sensor ASIC, can be arranged in the cover element 24, which is likewise of cylindrical form. The sensor 8 can be connected to a contact pad 13 located on the printed circuit board element 7 via an electrical connecting element 63, for example a cable or a flexible printed circuit board. The electrical connecting element 63 can be connected to the component 8 and/or to the contact pad 13 in particular in the open state of the electronic module 1 as shown in FIG. 8a. Once assembly has been effected, the cover element 24 can be pressed onto the frame element 14 with a small degree of pressing, for example.

FIG. 8b shows substantially the cover element 24 pressed onto the frame element 14. Displacement of the cover element 24 in relation to the frame element 14 makes it possible to set differently resulting component heights h₁, h₂, and therefore makes it possible to realize different sensor heights with in principle identical electronic module components.

In this case, the electrical connecting element 63 conforms to a required or desired sensor height h₁, h₂ by virtue of its deformability 70 and also the space available in the interior of the electronic module 1. Once a desired sensor height has been formed by virtue of the cover element 24 being suitably placed onto the frame element 14, the sensor height can be fixed sealingly by a fixing means 65, 66, for example by radial plastic welding.

FIG. 8c shows a further exemplary embodiment of a sensor housing, in which the sides of the cover element 24 have a shorter form than, for example, in FIGS. 8a, b. A still tight connection can be made, for example, by plastic laser welding 68 axially on the flat side of the cover element 24.

It is also the case in turn that additional fastening can be effected by way of a mechanical fastening element 69, for example a rivet, which absorbs mechanical stresses, such that the microstructuring 6 in turn only has to undertake substantially a sealing function.

1. An electronic module, comprising;
a printed circuit board element having at least one electronic component; and
a casing element connected to the printed circuit board element at least partially with a form fit,
wherein the at least one electronic component is arranged between the casing element and the printed circuit board element, and
wherein the form-fitting connection between the printed circuit board element and the casing element includes a microstructuring of the printed circuit board element.

2. The electronic module as claimed in claim 1, wherein the casing element is configured as a potting compound for the at least one electronic component.

3. The electronic module as claimed in claim 1, wherein the casing element defines an inner space and the at least one electronic component is arranged in the inner space.

4. The electronic module as claimed in claim 1, wherein the casing element is configured as a frame element.

5. The electronic module as claimed in claim 4, further comprising a cover element, which, together with the frame element, forms the casing element and has the inner space for the at least one electronic component.

6. The electronic module as claimed in claim 5, wherein at least one of the cover element and the frame element has microstructuring at least in part of a contact region between the cover element and the frame element.

7. The electronic module as claimed in claim 5, wherein the cover element is arranged in a vertically displaceable manner on the frame element.

8. The electronic module as claimed in claim 1, wherein one or more of (i) the at least one electronic component is arranged in a manner sealed off with respect to the outer region of the electronic element by the casing element and the printed circuit board element and (ii) the at least one electronic component is arranged in a manner sealed off with respect to the outer region of the electronic module in the inner region of the electronic module.

9. The electronic module as claimed in claim 1, wherein the printed circuit board element has at least one conductor element arranged on the surface, and wherein the conductor element has an at least partially microstructured form.

10. A control unit for a vehicle, comprising:
an electronic module including:
a printed circuit board element having at least one electronic component; and
a casing element connected to the printed circuit board element at least partially with a form fit,
wherein the at least one electronic component is arranged between the casing element and the printed circuit board element, and
wherein the form-fitting connection between the printed circuit board element and the casing element includes a microstructuring of the printed circuit board element.

11. (canceled)

12. A method for producing an electronic module, comprising:
microstructuring at least part of a surface of a printed circuit board element, the printed circuit board element having at least one electronic component;
applying a casing element to at least part of the surface of the printed circuit board element in the region of the microstructuring; and
forming a form fit between the casing element and the printed circuit board element using the microstructuring.
